(19) United States
(12) Patent Application Publication
(10) Pub. No.: US 2009/0242013 A1
(43) Pub. Date: Oct. 1, 2009

(54) SOLAR CELL MODULE

(75) Inventor: Mikio TAGUCHI, Hirakata City (JP)

Correspondence Address: MOTS LAW, PLLC, 1629 K STREET N.W., SUITE 602, WASHINGTON, DC, 20006-1635, US

(73) Assignee: SANYO ELECTRIC CO., LTD., Moriguchi City (JP)

(21) Appl. No.: 12/372,126

(22) Filed: Feb. 17, 2009

(30) Foreign Application Priority Data
Mar. 31, 2008 (JP) JP2008-090261

(51) Int. Cl. H01L 31/052; H01L 31/00

(52) U.S. Cl. 136/246; 136/256

(57) ABSTRACT

A solar cell and a sealing material provided on a light entering side of the solar cell are included. The solar cell includes a photoelectric conversion body and a fine line-shaped electrode formed on a light receiving surface of the photoelectric conversion body so as to extend in one direction. Additionally, a low-refractive-index layer having a refractive index lower than a refractive index of the sealing material is provided between a light receiving surface of the fine line-shaped electrode and the sealing material so as to cover the light receiving surface of the fine line-shaped electrode. The low-refractive-index layer has an inclined surface whose central portion projects in a cross section of the low-refractive-index layer taken along a different direction perpendicular to the one direction, and the inclined surface is inclined toward the light receiving surface of the photoelectric conversion body.

### CROSS REFERENCE TO RELATED APPLICATIONS

This application claims priority based on 35 USC 119 from prior Japanese Patent Application No. P2008-090261 filed on Mar. 31, 2008, entitled “Solar Cell Module”, the entire contents of which are incorporated herein by reference.

### BACKGROUND OF THE INVENTION

1. Field of the Invention

The present invention relates to a solar cell module having a plurality of solar cells sealed with a sealing material.

2. Description of Related Art

FIG. 10 is a conceptual sectional view of a solar cell module 1. As illustrated, a plurality of solar cells 3 electrically connected to each other by wiring 2 are sealed with sealing material 105 between light-receiving-surface member 103 and rear-surface member 104.

Each of solar cells 3 includes photoelectric conversion body 5 having a photoelectric conversion function and collecting electrode 4 provided on a light receiving surface of photoelectric conversion body 5, as shown in a plan view seen from the light receiving surface side in FIG. 11. Collecting electrode 4 has a plurality of fine line-shaped electrodes 4A and connecting electrodes 4B. Each of fine line-shaped electrodes 4A is provided in parallel to other fine line-shaped electrodes 4A across a substantially entire region of the light receiving surface of photoelectric conversion body 5. Connecting electrodes 4B are provided to extend perpendicularly to a longitudinal direction of fine line-shaped electrodes 4A. Wiring 2 is adhered onto connecting electrodes 4B with an adhesive so as to electrically connect adjacent solar cells 3 to each other.

Solar cell module 1 generates electricity when light enters photoelectric conversion bodies 5. At this time, since part of the light that is entering photoelectric conversion body 5 of each of solar cells 3 is interrupted by collecting electrodes 4 provided on the light receiving surface side of photoelectric conversion body 5, that part of the light does not contribute to the generation of electricity. To mitigate this problem, a structure is known in which, in order to increase the light that enters photoelectric conversion body 5, bubbles are formed within sealing material 105 on fine line-shaped electrode 4A to refract the light that has entered collecting electrode 4 and guide the light to photoelectric conversion body 5 (see, for example, Japanese Patent Application Publication No. 2006-40937).

In conventional solar cell module 1, such bubbles are formed within sealing material 105 by adding a foaming agent to fine line-shaped electrodes 4A, and then by evaporating the foaming agent with heat applied at the time of manufacturing solar cell module 1.

However, this method has a problem in that it is difficult to uniformly form the bubbles on fine line-shaped electrodes 4A. Accordingly, light that enters the surface of each of fine line-shaped electrodes 4A cannot be sufficiently guided to photoelectric conversion body 5. Consequently, output of solar cell module 1 is not improved as much as desired.

### SUMMARY OF THE INVENTION

An aspect of the invention provides a solar cell module that comprises: a solar cell that comprises a photoelectric conversion body and a fine line-shaped electrode formed on a light receiving surface of the photoelectric conversion body so as to extend in one direction; and a sealing material provided on a light entering side of the solar cell, wherein the solar cell comprises a low-refractive-index layer disposed between a light receiving surface of the fine line-shaped electrode and the sealing material, the low-refractive-index layer has a refractive index lower than a refractive index of the sealing material, the low-refractive-index layer is provided so as to cover the light receiving surface of the fine line-shaped electrode, and the low-refractive-index layer has an inclined surface being inclined, so that its central portion projects in a cross section of the low-refractive-index layer taken along a different direction perpendicular to the one direction, and that the cross section becomes wider toward the light receiving surface of the photoelectric conversion body.

Another aspect of the invention provides a solar cell module that comprises: a plurality of solar cells arranged in an arrangement direction; a wiring extending in the arrangement direction and configured to electrically connect the solar cells disposed adjacent to each other; and a sealing material provided on light entering sides of the plurality of solar cells wired to each other with the wiring, wherein each of the solar cells comprises: a photoelectric conversion body; and a low-refractive-index layer disposed between a light receiving surface of the wiring and the sealing material, the low-refractive-index layer having a refractive index lower than a refractive index of the sealing material, the low-refractive-index layer is provided so as to cover a light receiving surface of the wiring, and the low-refractive-index layer has an inclined surface being inclined, so that its central portion projects in a cross section of the low-refractive-index layer taken along a direction perpendicular to the arrangement direction, and that the cross section becomes wider toward a light receiving surface of the photoelectric conversion body.

### BRIEF DESCRIPTION OF THE DRAWINGS

FIG. 1 is a conceptual view of a solar cell module according to a first embodiment;

FIGS. 2A and 2B are respectively a plan view and a sectional view of a solar cell according to the first embodiment;

FIGS. 3A to 3C are views showing configuration of the solar cell and a low-refractive-index layer according to the first embodiment;

FIG. 4 is a schematic view showing an optical path of incident light in the solar cell module according to the first embodiment;

FIG. 5 is a schematic view showing the optical path of incident light in the solar cell module according to the first embodiment;

FIG. 6 is a schematic view showing the optical path of incident light in the solar cell module according to the first embodiment;

FIG. 7 is a schematic view showing an optical path of incident light in a solar cell module according to a second embodiment;

FIG. 8 is a schematic view showing the optical path of incident light in the solar cell module according to the second embodiment;

FIGS. 9A and 9B are views showing configuration of a wiring and a low-refractive-index layer in a solar cell module according to a third embodiment;

FIG. 10 is a conceptual view of a solar cell module in a related art; and

FIG. 11 is a plan view of a solar cell in a related art.

### DETAILED DESCRIPTION OF EMBODIMENTS

Descriptions are provided hereinbelow for embodiments based on the drawings. In the respective drawings referenced herein, the same constituents are designated by the same reference numerals and duplicate explanation concerning the same constituents is basically omitted. All of the drawings are provided to illustrate the respective examples only. No dimensional proportions in the drawings shall impose a restriction on the embodiments. For this reason, specific dimensions and the like should be interpreted with the following descriptions taken into consideration. In addition, the drawings include parts whose dimensional relationship and ratios are different from one drawing to another.

### First Embodiment

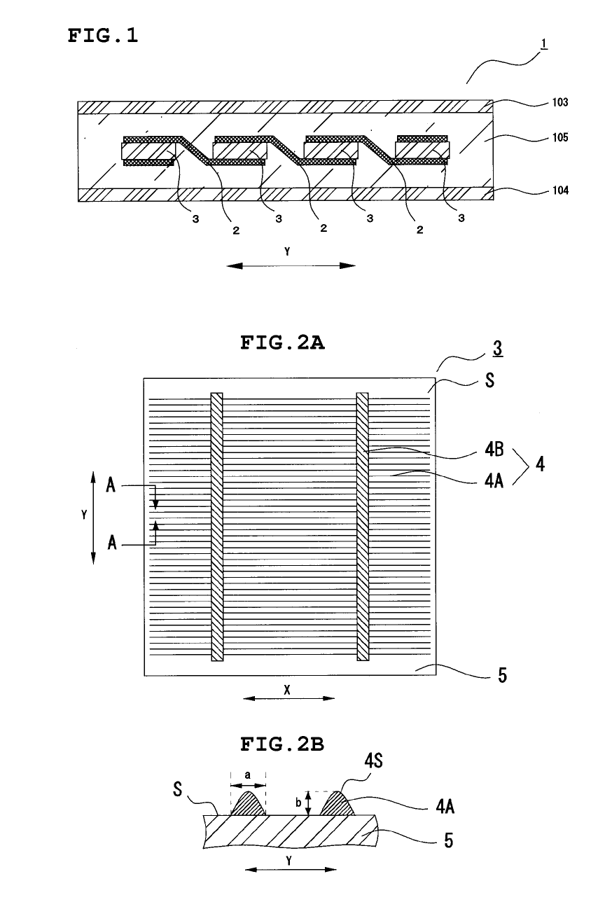

First, description will be given of solar cell module 1 according to a first embodiment of the present invention, using FIG. 1 to FIG. 5.

### (Configuration of Solar Cell Module)

FIG. 1 is a conceptual sectional view showing a configuration of solar cell module 1 according to the present embodiment. Solar cell module 1 includes a plurality of solar cells 3 arranged in arrangement direction Y, light-receiving-surface member 103, sealing material 105, and rear-surface member 104. Solar cells 3 adjacent to each other are electrically connected by wiring 2 that extends in arrangement direction Y.

Wiring 2 is made of a metallic material such as a copper foil. The metallic material may be exposed from the surface of wiring 2, or the surface may be covered with a conductive material such as tin. Wiring 2 is adhered with an adhesive onto connecting electrode 4B formed on a light receiving surface of photoelectric conversion body 5. As the adhesive, a meltable metallic material such as solder or a conductive adhesive such as a conductive resin adhesive can be used. Direct electric connection may be made by directly contacting wiring 2 with connecting electrode 4B. Alternatively, mechanical connection may be made with an adhesive. In this case, in addition to the conductive adhesive, an insulating adhesive can be used.

Light-receiving-surface member 103 having translucency is adhered onto the light entering side of solar cell 3 with sealing material 105 having translucency. With such configuration of light-receiving-surface member 103 and sealing material 105, sealing material 105 is arranged on the light entering side of solar cell 3 and wiring 2. Light-receiving-surface member 103 is made of a material having translucency, such as glass or translucent plastics, for example.

Moreover, rear-surface member 104 is adhered onto a rear surface side of solar cell 3 with sealing material 105. Rear-surface member 104 is made of, for example: a resin film such as PET; a laminated film having a structure in which an Al foil is sandwiched between resin films; or the like.

Sealing material 105 is, for example, a resin having translucency, such as EVA and PVB, and also functions to seal solar cell 3.

A terminal box for power extraction, which is not shown, is arranged, for example, on a rear surface of rear-surface member 104. Furthermore, a frame is attached to an outer periphery of solar cell module 1 when necessary.

In manufacturing such solar cell module 1, first, light-receiving-surface member 103, sealing material 105, a plurality of solar cells 3, sealing material 105, and rear-surface member 104 are stacked sequentially to form a stacked body. Next, the stacked body is heated while pressure is applied to the stacked body from the top and bottom thereof, so that solar cell module 1 is structurally completed.

### (Configuration of Solar Cell)

FIG. 2A is a plan view of solar cell 3 according to this embodiment as seen from the light receiving surface side. Solar cell 3 has photoelectric conversion body 5 and collecting electrode 4 formed on light receiving surface S of photoelectric conversion body 5, as shown in FIG. 2A. Photoelectric conversion body 5 is made of a semiconductor material having a semiconductor junction such as a pn junction and a pin junction. Examples of the semiconductor material that can be used include: crystalline silicon semiconductors such as single crystal silicon and polycrystalline silicon; and semiconductor materials made of well-known semiconductor materials such as compound semiconductors such as GaAs, amorphous silicon based thin film semiconductors, compound thin film semiconductors, etc. Examples of a material that can be used to form the semiconductor junction with the above-mentioned semiconductor materials include crystal semiconductors, amorphous semiconductors, compound semiconductors, and other well-known semiconductor materials.

As shown in the plan view of FIG. 2A, collecting electrode 4 formed on light receiving surface S of photoelectric conversion body 5 has a plurality of fine line-shaped-electrodes 4A of a thin line shape and connecting electrode 4B to which wiring 2 is connected. Fine line-shaped electrodes 4A collect electrons or holes generated by light that has been absorbed by photoelectric conversion body 5. Connecting electrode 4B also functions as a bus electrode that collects the carriers collected by fine line-shaped electrodes 4A. Connecting electrode 4B is formed to extend in arrangement direction Y. Fine line-shaped electrodes 4A extend in direction X perpendicular to arrangement direction Y of solar cell 3. Fine line-shaped electrodes 4A are arranged approximately parallel to each other and spaced from each other at an approximately equal interval. An electrode provided on the rear surface of solar cell 3 may have the same structure as that of collecting electrode 4 on light receiving surface S, or may have a shape different from that of collecting electrode 4.

Collecting electrode 4 is formed of, for example, a thermosetting type conductive paste including an epoxy resin as a binder and conductive particles as a filler. In the case of a single crystal silicon solar cell, a polycrystalline silicon solar cell, or the like, the constitution of collecting electrode 4 is not limited to this. A sintered paste including a metal powder such as silver and aluminum, a glass frit, or an organic vehicle, etc., may be used. Alternatively, collecting electrode 4 may be formed using generally-available metallic materials such as silver and aluminum. The thermosetting type conductive paste and the sintered paste are formed by a screen printing method or the like.

FIG. 2B is an enlarged sectional view of a principal part between A-A in arrangement direction Y shown in FIG. 2A. As shown in FIG. 2B, generally using the screen printing method, fine line-shaped electrode 4A is formed so as to have inclined surface 4S being inclined, so that its central portion projects in a cross section of fine line-shaped electrode 4A taken along arrangement direction Y perpendicular to the direction X, and that the cross section becomes wider toward light receiving surface S of photoelectric conversion body 5. Fine line-shaped electrode 4A is also formed to have width a of approximately 50 μm to 150 μm and thickness b of approximately 5 μm to 50 μm. The size and number of fine line-shaped electrode 4A are set as appropriately, in consideration of size, physical properties, and the like of photoelectric conversion body 5.

### (Formation of Low-Refractive-Index Layer)

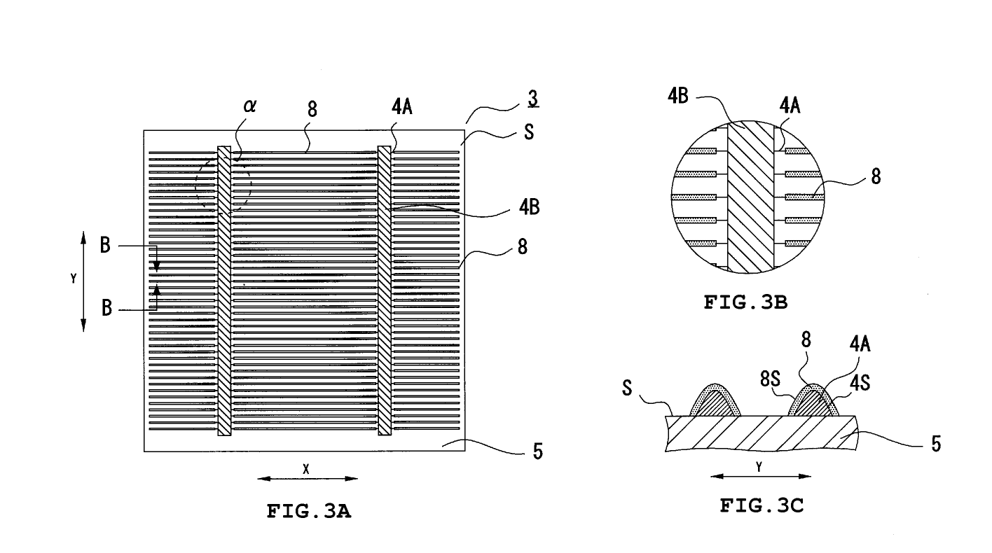

FIG. 3A is a plan view for illustrating a configuration relationship between fine line-shaped electrode 4A and low-refractive-index layer 8. FIG. 3B is an enlarged view of a principal part within region a shown in FIG. 3A. FIG. 3C is an enlarged sectional view of a principal part between B-B in arrangement direction Y shown in FIG. 3A. As shown in the FIG. 3C, in the present embodiment, low-refractive-index layer 8 is provided on inclined surface 4S, which is a light receiving surface of fine line-shaped electrode 4A that extends in direction X. At this time, since wiring 2 mentioned above is connected onto connecting electrode 4B so as to extend in arrangement direction Y, low-refractive-index layer 8 is not provided on connecting electrode 4B and fine line-shaped electrode 4A in the vicinity of the connecting electrode 4B, as shown in FIGS. 3A and 3B. Accordingly, low-refractive-index layer 8 is formed on the surface of fine line-shaped electrode 4A exposed from wiring 2. As shown in FIG. 3C, low-refractive-index layer 8 is provided so as to cover the light receiving surface of fine line-shaped electrode 4A having inclined surface 4S. In this manner, low-refractive-index layer 8 has inclined surface 8S being inclined, so that its central portion projects, in a cross section of low-refractive-index layer 8 taken along arrangement direction Y toward light-receiving-surface member 103, and that the cross section becomes wider toward light receiving surface S of photoelectric conversion body 5 as in the case of fine line-shaped electrode 4A.

Low-refractive-index layer 8 has a refractive index lower than the refractive index of sealing material 105. For example, the refractive index of EVA that is used most often as sealing material 105 is approximately 1.45 to 1.50. Accordingly, when EVA is used as sealing material 105, low-refractive-index layer 8 has a refractive index lower than 1.45. Such low-refractive-index layer 8 can be made from, for example, a silicone resin material having silica nano particles blended therein, or fluorine polymer materials. Low-refractive-index layer 8 produced with this method has a refractive index of approximately 1.32.

Specifically, the resin material using silica nano particles can be produced by reacting a silica sol, obtained by hydrolysis polycondensation of alkoxysilane, with alkoxysilane or a partial hydrolyzate thereof, and then by including silica nano particles in the reaction product. Alternatively, the resin material can also be produced by blending silica nano particles with alkoxysilane partially hydrolyzed in a similar manner, or by mixing silica nano particle with a silicone material. Thus, use of a hybrid material that is a mixture of an organic material and an inorganic material can facilitate production of a layer with a low refractive index.

A silane coupling material or the like may be added in production of low-refractive-index layer 8. This can improve adhesion of low-refractive-index layer 8 to fine line-shaped electrode 4A or sealing material 105, thereby improving long term stability.

As the fluorine polymer materials, a low-refractive-index material (refractive index n=1.34) such as amorphous fluororesin can be used.

These materials are easy to handle. These materials can be easily applied using methods such as screen printing to form low-refractive-index layer 8. The thickness of low-refractive-index layer 8 can be controlled by controlling the amount of application. Therefore, the size and shape of low-refractive-index layer 8 can be optimized easily, depending on the refractive index of a low-refractive-index material to be applied.

### (Effects and Advantages)

Hereinafter, effects and advantages of the solar cell module according to this embodiment will be described.

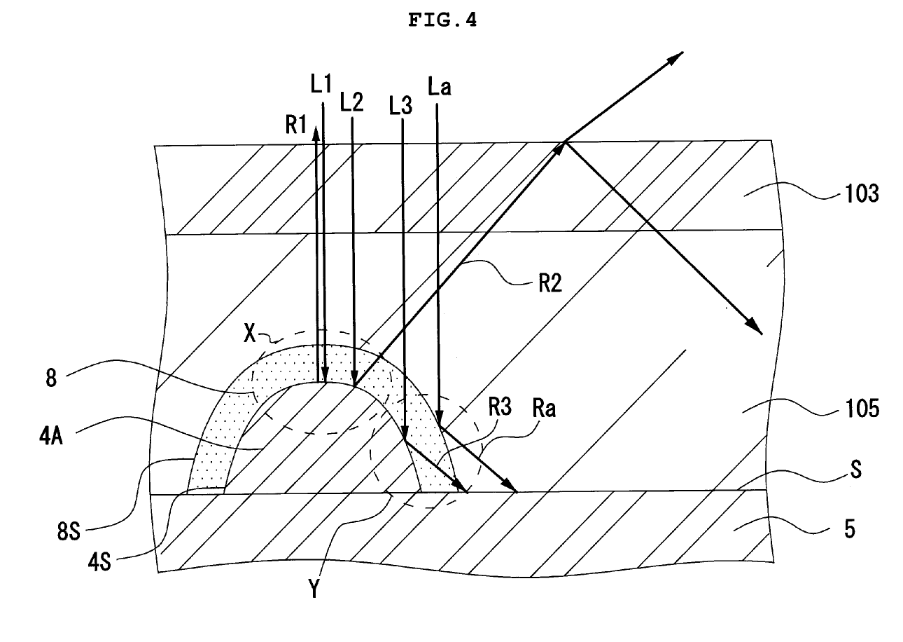

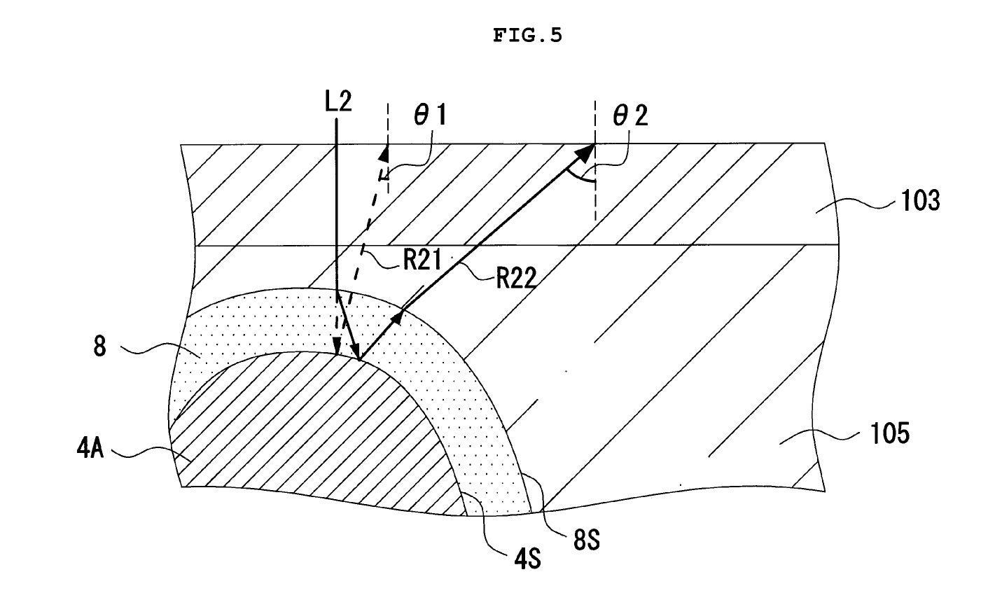

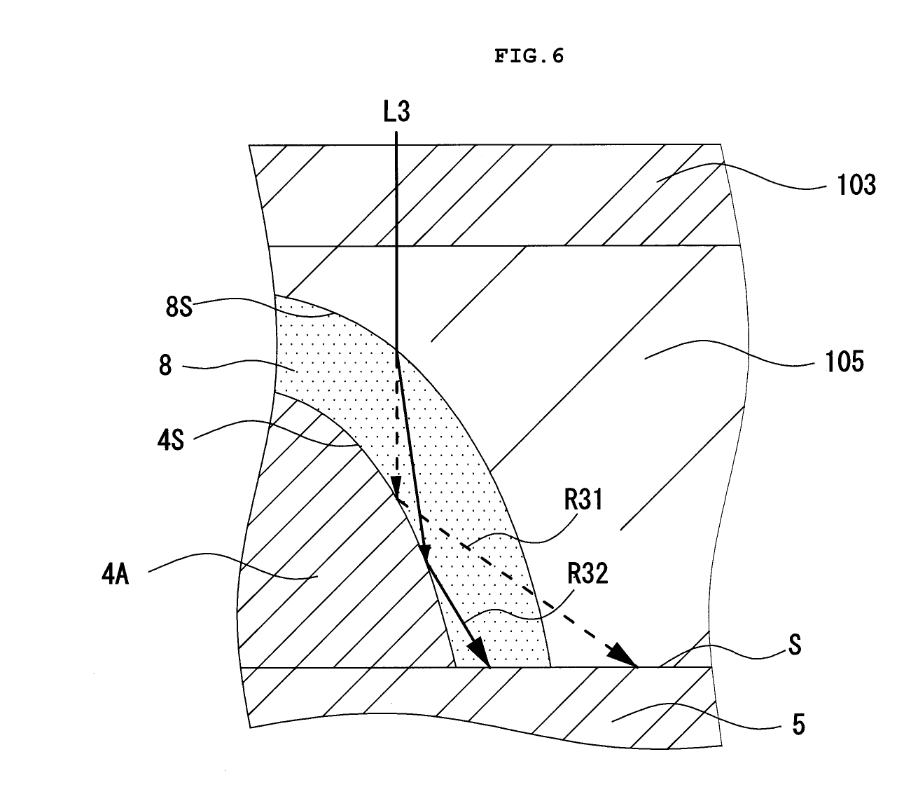

FIG. 4 is a schematic view for describing an optical path of incident light in the solar cell module according to the embodiment. FIG. 5 is an enlarged view of a principal part of a region surrounded by X of FIG. 4. FIG. 6 is an enlarged view of a principal part of a region surrounded by Y of FIG. 4. In FIGS. 5 and 6, for comparison, a solid line indicates the optical path of the light in the module according to the embodiment, while a dashed line indicates an optical path of light in a comparison module not including low-refractive-index layer 8.

As shown in FIG. 4, beams of light transmit through light-receiving-surface member 103 and enter fine line-shaped electrode 4A, in both of the module according to the present embodiment and the comparison module. Among them, in both modules light L1 that enters near the top part of fine line-shaped electrode 4A is reflected back to light-receiving-surface member 103 with very little entering photoelectric conversion body 5.

The region surrounded by X shown in FIG. 4 is a region near the top part of inclined surface 8S of low-refractive-index layer 8. Light L2 that enters inclined surface 8S in this region is reflected to the light-receiving-surface member 103 side by fine line-shaped electrode 4A. Then, due to a difference between the refractive index of air and that of light-receiving-surface member 103, part of light 2 is again reflected to the photoelectric conversion body 5 side, and enters photoelectric conversion body 5. That part of light 2 contributes to generation of electricity. The region surrounded by Y shown in FIG. 4 is a region near light receiving surface S of photoelectric conversion body 5 of inclined surface 8S of low-refractive-index layer 8. The light that enters this region includes light R3 reflected by fine line-shaped electrode 4A and light Ra totally reflected by low-refractive-index layer 8S. Part of light L3 reaches fine lined-shaped electrode 4A, where the part of light L3 has entered low-refractive-index layer 8 at an angle smaller than the critical angle that satisfies a total reflection condition because of a relation between the refractive index of low-refractive-index layer 8 and that of sealing material 105. Then, that part of light L3 is reflected by inclined surface 4S and enters photoelectric conversion body 5. Light La that enters low-refractive-index layer 8 at an angle larger than the critical angle is totally reflected by inclined surface 8S of low-refractive-index layer 8S, and enters photoelectric conversion body 5.

Hereinafter, the light that enters the regions surrounded by X and Y shown in FIG. 4 will be described in detail.

As shown in FIG. 5, in the case of the comparison module indicated by the dashed line, light L2 that enters region X goes straight, enters inclined surface 4S of fine line-shaped electrode 4A, and is reflected by inclined surface 4S. Subsequently, since the refractive indexes of sealing material 105 and light-receiving-surface member 103 are approximately equal, reflected light R21 goes straight, as it enters, within sealing material 105 and light-receiving-surface member 103. Reflected light R21 enters an interface between light-receiving-surface member 103 and air at incident angle θ1. Then, among beams of light that enter this interface, the light having incident angle θ1 larger than the critical angle that satisfies the total reflection condition is totally reflected to the photoelectric conversion body 5 side at the interface. The light having incident angle θ1 smaller than the critical angle is refracted at the interface; a great part of that light is radiated into the air, and therefore does not contribute to generation of electricity. Here, when light-receiving-surface member 103 is a glass, the critical angle is approximately 41.8 degrees, where the refractive index of glass is approximately 1.5 and the refractive index of air is approximately 1.0.

On the other hand, in the case of the module according to present embodiment indicated by the solid line, light L2 that enters region X is refracted at the interface between sealing layer 105 and low-refractive-index layer 8 due to the difference between the refractive index of sealing layer 105 and that of low-refractive-index layer 8. At this time, since the refractive index of low-refractive-index layer 8 is lower than the refractive index of sealing layer 105, the angle of refraction becomes larger than the incident angle. Accordingly, the refracted light reaches inclined surface 4S of fine line-shaped electrode 4A on the photoelectric conversion body 5 side, compared with the comparison module indicated by the dashed line. Accordingly, the incident angle of light L2 to fine line-shaped electrode 4A becomes large compared with the incident angle in the comparison module indicated by the dashed line. Then, light L2 is reflected by inclined surface 4S. Also at this time, the module according to the embodiment has a larger angle of reflection. Reflected light R22 is again refracted at the interface between low-refractive-index layer 8 and sealing material 105, and goes straight, as it is refracted, within sealing material 105 and light-receiving-surface member 103. Then, reflected light R22 enters the interface between light-receiving-surface member 103 and air at incident angle θ2. Subsequently, among beams of light that enter the interface, the light having incident angle θ2 larger than the above-mentioned critical angle is totally reflected to the photoelectric conversion body 5 side at the interface. The light having incident angle θ2 smaller than the critical angle is refracted at the interface; a great part of that light is radiated into the air, and therefore, does not contribute to generation of electricity.

At this time, when the module according to the embodiment and the comparison module are compared, in the module according to the embodiment, the refracted light reaches inclined surface 4S of fine line-shaped electrode 4A on the photoelectric conversion body 5 side compared with the comparison module. Additionally, the incident angle at the time is larger than the incident angle in the comparison module, and the angle of reflection at inclined surface 4S in the module according to the embodiment is also larger that in the comparison module. For this reason, in the module according to the embodiment, incident angle θ2 at the time when reflected light R22 enters the interface between light-receiving-surface member 103 and air becomes larger than incident angle θ1 in the comparison module. Consequently, according to the present embodiment, among beams of light that are reflected on inclined surface 4S of fine line-shaped electrode 4A and reaches the interface between light-receiving-surface member 103 and air, a proportion of light whose incident angle to the interface satisfies the total reflection condition is increased compared to that in the comparison module. Therefore, according to the present embodiment, the amount of light that is totally reflected at the interface between light-receiving-surface member 103 and air, and enters photoelectric conversion body 5 again can be increased compared with the case of the comparison module, and thereby more effective use of light is attained.

Next, description will be given of an optical path of light that enters region Y. As shown in FIG. 6, in the case of the comparison module indicated by the dashed line, incident light L3 goes straight and enters inclined surface 4S of line-shaped electrode 4A, and reflected light R31 enters photoelectric conversion body 5.

On the other hand, in the case of the module according to the embodiment indicated by the solid line, light L3 that enters region Y is refracted due to the difference between the refractive index of sealing layer 105 and that of low-refractive-index layer 8. At this time, since the refractive index of low-refractive-index layer 8 is lower than the refractive index of sealing layer 105, the angle of refraction becomes larger than the incident angle. For this reason, the refracted light reaches inclined surface 4S of fine line-shaped electrode 4A on the photoelectric conversion body 5 side compared with the case of the comparison module indicated by the dashed line. Accordingly, the incident angle of light L3 to fine line-shaped electrode 4A becomes larger than the incident angle in the comparison module indicated by the dashed line. Then, light L3 is reflected by inclined surface 4S. The angle of reflection at this time is also larger than the angle of reflection in the comparison module. Then, reflected light R32 enters photoelectric conversion body 5.

When the module according to the embodiment and the comparison module are compared, in the module according to the embodiment, the refracted light reaches inclined surface 4S of fine line-shaped electrode 4A on the photoelectric conversion body 5 side compared with the case of the comparison module. Additionally, the incident angle at the time is larger than the incident angle in the comparison module, and the angle of reflection at inclined surface 4S in the module according to the present embodiment is also larger than that in the comparison module. For this reason, according to the present embodiment, a distance until the reflected light reaches light receiving surface S of photoelectric conversion body 5 can be made shorter than that in the comparison module. Accordingly, according to the present embodiment, the amount of light absorbed by low-refractive-index layer 8 or sealing layer 105 before the reflected light reaches light receiving surface S can be reduced compared with that in the prior art, and thereby more effective use of light is attained.

As explained above, according to the present embodiment, the light that has not been able to contribute to generation of electricity in the prior art can be used effectively. Thus, a solar cell module having an improved output can be provided.

Moreover, since low-refractive-index layer 8 is used in this embodiment, no bubble enters the interface between solar cell 3 and sealing layer 105. Therefore, the solar cell module according to the present invention has high reliability compared with the conventional solar cell module using the bubbles. Furthermore, adhesion of low-refractive-index layer 8 to sealing layer 105 can be improved by adding a material that improves adhesion of sealing layers 105, such as the silane coupling material, to low-refractive-index layer 8, thereby greatly improving reliability.

### Second Embodiment

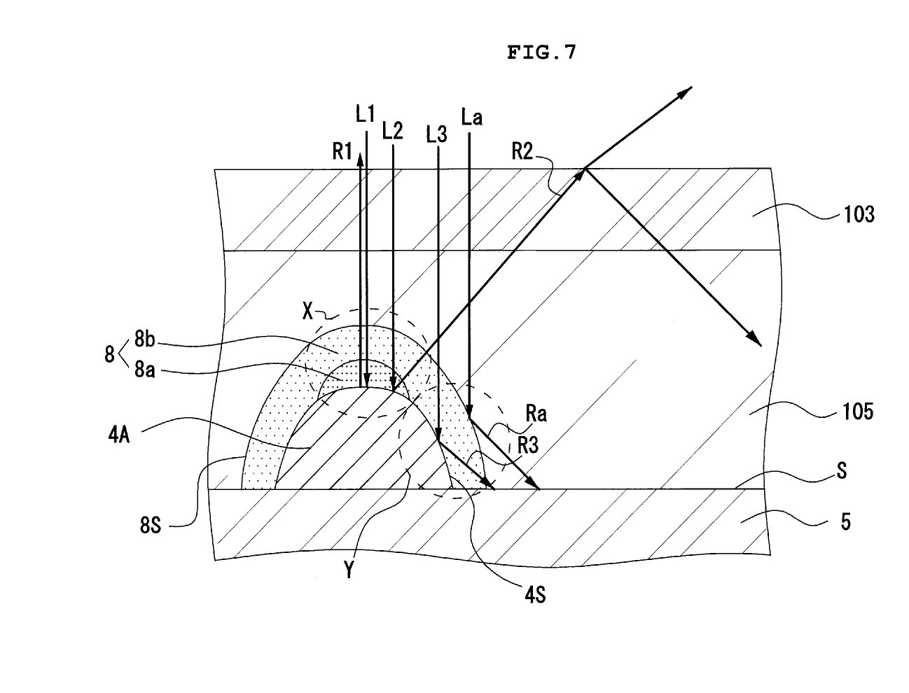

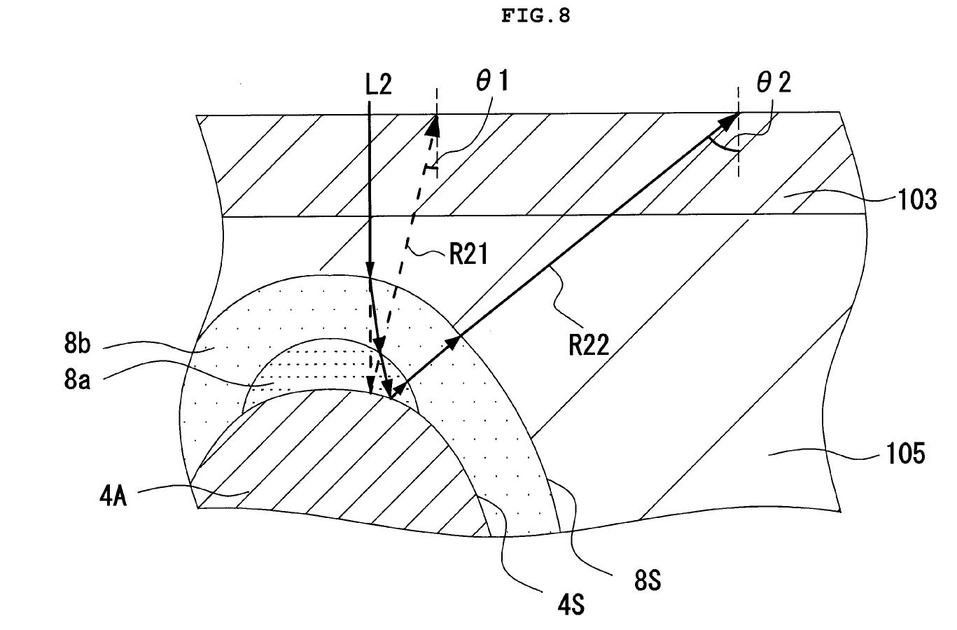

A second embodiment of the present invention will be described referring to FIGS. 7 and 8. In the description below, description on identical or similar parts to those in the first embodiment will be omitted.

### (Configuration of Low-Refractive-Index Layer)

FIG. 7 is a schematic sectional view for describing effects of low-refractive-index layer 8 according to the present embodiment. FIG. 8 is an enlarged view of a principal part of light that enters a region surrounded by X of FIG. 7. For comparison, an optical path of light in a comparison module not including low-refractive-index layer 8 is indicated by a dashed line in the drawing. Since the optical path of the light in the comparison module is the same as that of the first embodiment mentioned above, description thereof will be omitted here.

Unlike the first embodiment, the present embodiment includes low-refractive-index layer 8 having two layers of first low-refractive-index layer 8a and second low-refractive-index layer 8b. As shown in FIG. 7, first low-refractive-index layer 8a is formed on an upper portion of fine line-shaped electrode 4A so as to uncover lower surfaces of fine line-shaped electrode 4A. Moreover, second low-refractive-index layer 8b is formed to extend over the lower surfaces of fine line-shaped electrode 4A and the surface of first low-refractive-index layer 8a. Additionally, second low-refractive-index layer 8b has a refractive index lower than the refractive index of sealing material 105, and first low-refractive-index layer 8a has a refractive index lower than the refractive index of second low-refractive-index layer 8b. In the present embodiment, such a configuration of low-refractive-index layer 8 makes inclination of inclined surface 8S of low-refractive-index layer 8 larger than inclination of inclined surface 8S in the first embodiment.

A shown in FIG. 7, similarly to the first embodiment, among beams of light that enter the region surrounded by X, light L1 that enters near the top part of fine line-shaped electrode 4A is reflected back to the light-receiving-surface member 103 side with entering photoelectric conversion body 5.

As shown in FIG. 8, in the region surrounded by X, incident light L2 that enters inclined surface 8S is refracted at an interface between sealing layer 105 and second low-refractive-index layer 8b due to a difference between the refractive index of sealing layer 105 and that of second low-refractive-index layer 8b. At this time, since the refractive index of second low-refractive-index layer 8b is lower than the refractive index of sealing layer 105, the angle of refraction becomes larger than the incident angle. Subsequently, incident light L2 is refracted at an interface between second low-refractive-index layer 8b and first low-refractive-index layer 8a due to a difference between the refractive index of second low-refractive-index layer 8b and that of first low-refractive-index layer 8a. At this time, since the refractive index of first low-refractive-index layer 8a is lower than the refractive index of second low-refractive-index layer 8b, the angle of refraction becomes large rather than the incident angle, so that the refracted light reaches inclined surface 4S of fine line-shaped electrode 4A on the photoelectric conversion body 5 side compared with the comparison module indicated by the dashed line.

As the result, according to the present embodiment, compared with the case of the first embodiment, a position at which incident light L2 reaches inclined surface 4S of fine line-shaped electrode 4A can be brought closer to the photoelectric conversion body 5 side. The incident angle at the time can be enlarged. For this reason, according to the present embodiment, the angle of reflection of reflected light R22 reflected on inclined surface 4S of fine line-shaped electrode 4A can be made larger than that in the first embodiment. Thus, incident angle θ2 at which reflected light R22 enters the interface between air and light-receiving-surface member 103 can be made larger than that in the first embodiment. Accordingly, according to the embodiment, among beams of light that are reflected on inclined surface 4S of fine line-shaped electrode 4A and that reaches the interface between light-receiving-surface member 103 and air, a proportion of light whose incident angle to the interface satisfies the total reflection condition can be further increased, and thereby more effective use of light is attained.

Moreover, similarly to the case of the first embodiment, among beams of light that enter the region surrounded by Y shown in FIG. 7, the light as indicated by incident light L3 is reflected on inclined surface 4S of fine line-shaped electrode 4A and enters photoelectric conversion body 5, where incident light L3 has entered at an angle smaller than the critical angle that satisfies the total reflection condition because of the relation between the refractive index of second low-refractive-index layer 8b and that of sealing material 105. Additionally, light that enters at an angle larger than the critical angle is totally reflected on inclined surface 8S of second low-refractive-index layer 8b, and enters photoelectric conversion body 5, as indicated by incident light La. At this time, since formation of first low-refractive-index layer 8a can make the inclination of inclined surface 8S of low-refractive-index layer 8 far steeper, the distance until the reflected light reaches light receiving surface S of photoelectric conversion body 5 can be made far shorter than that in the first embodiment. Accordingly, the amount of light absorbed by second low-refractive-index layer 8b or sealing layer 105 before the reflected light reaches light receiving surface S can be further reduced compared to the case in the first embodiment.

As explained above, according to the present embodiment, the light that has not been able to contribute to generation of electricity in the prior art can be used much more effectively. Thus, a solar cell module having an improved output can be provided.

Moreover, since low-refractive-index layer 8 is used in this embodiment, no bubble enters the interface between solar cell 3 and sealing layer 105. Therefore, the solar cell module according to the present invention has high reliability compared with the conventional solar cell module using the bubbles.

### Third Embodiment

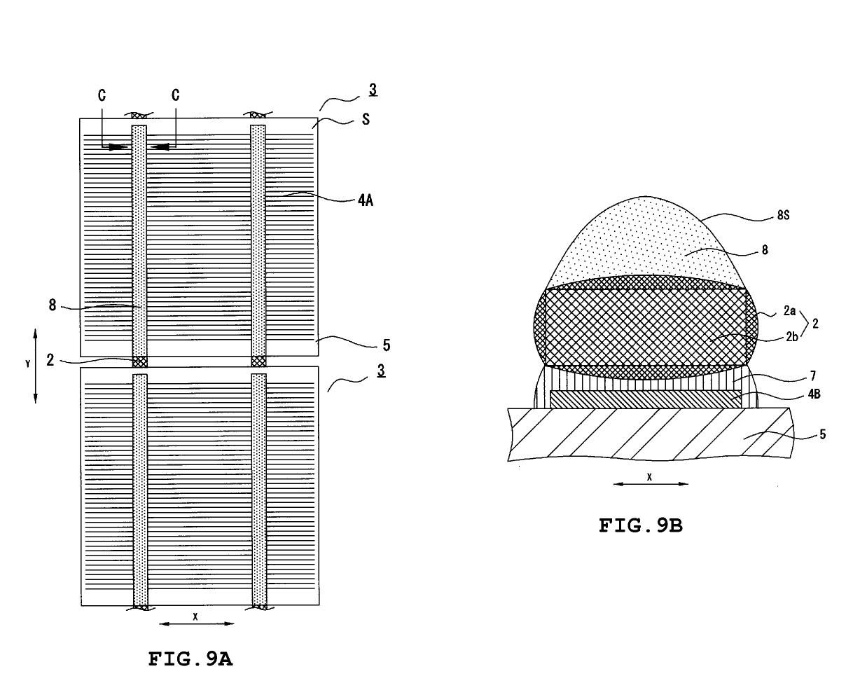

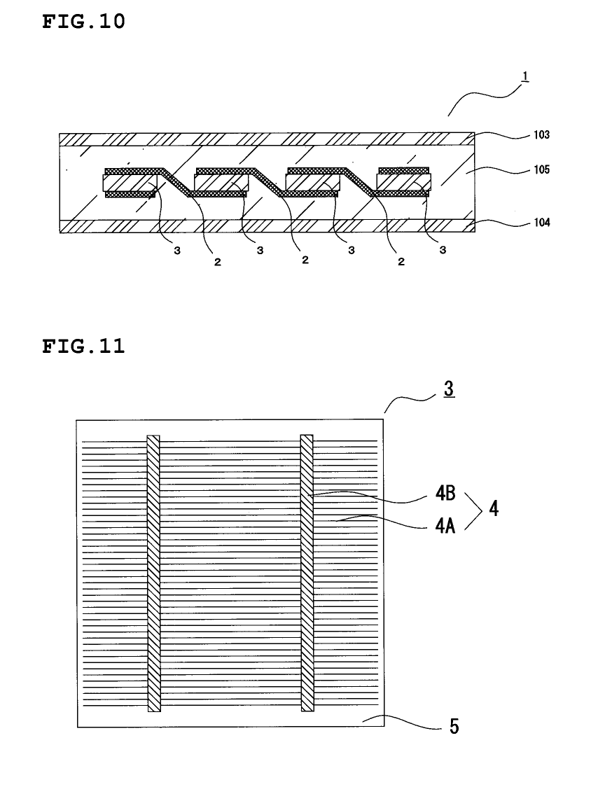

A third embodiment of the invention will be described referring to FIGS. 9A and 9B. In the description below, description on identical or similar parts to those in the first embodiment will be omitted.

### (Formation of Solar Cell Module)

FIG. 9A is a plan view of a light receiving surface side of a solar cell module according to the present embodiment, and FIG. 9B is an enlarged sectional view of a principal part between C-C shown in FIG. 9A.

Unlike the first and second embodiments, in the present embodiment, low-refractive-index layer 8 is provided on wiring 2.

As shown in FIG. 9A, wiring 2 is disposed in arrangement direction Y of solar cell 3. Then, as shown in FIG. 9B, wiring 2 is connected on connecting electrode 4B.

As shown in FIG. 9B, wiring 2 has: core material 2b made of a metallic material such as copper; and conductive layer 2a that is made of tin, solder, or the like, and that covers the surface of this core material 2b. Conductive layer 2a can be formed, for example, using a dip method. Conductive layer 2a of wiring 2 has an inclined surface that becomes wider from the sealing material 105 side toward the core material 2b side. Accordingly, low-refractive-index layer 8 formed so as to cover a light receiving surface of conductive layer 2a has inclined surface 8S being inclined, so that its central portion projects in a cross section of low-refractive-index layer 8 taken along direction X perpendicular to arrangement direction Y, and that the cross section becomes wider toward light receiving surface S of photoelectric conversion body 5.

A material of low-refractive-index layer 8 can be applied onto wiring 2 with a dispenser or the like. At this time, the material of low-refractive-index layer 8 is applied in 2 steps: at the first step, applied to the central portion of wiring 2 and, at the second step, to the whole region of wiring 2. Thereby, inclined surface 8S can be formed, in which the central portion projects in the cross section of low-refractive-index layer 8 taken along direction X perpendicular to arrangement direction Y. Inclined surface 8S is inclined, so that the cross section becomes wider toward light receiving surface S of photoelectric conversion body 5. Low-refractive-index layer 8 on wiring 2 may be formed after connection between connecting electrode 4B and wiring 2, or before the connection.

Also in the present embodiment, among beams of reflected light reflected on the light receiving surface of conductive layer 2a in wiring 2, a proportion of light (that is reflected to the light-receiving-surface member 103 side, is totally reflected at the interface between light-receiving-surface member 103 and air, and then enters photoelectric conversion body 5 again) can be increased, and thereby more effective use of light is attained.

Moreover, a distance until the reflected light reflected to the photoelectric conversion body 5 side, among beams of reflected light reflected on the light receiving surface of conductive layer 2a, reaches light receiving surface S can be shortened. Therefore, the amount of light absorbed by low-refractive-index layer 8 or sealing layer 105 can be reduced, and more effective use of light can be attained, compared to the case in the prior art.

As the result, according to the present embodiment also, the amount of light that enters the photoelectric conversion body can be increased. Thus, a solar cell module having an improved output can be provided.

Moreover, since low-refractive-index layer 8 is used in the embodiment, the solar cell module according to the present invention has high reliability compared with the conventional solar cell module using the bubbles.

### (Modification)

As has been described above, according to the present embodiments, it is possible to provide a solar cell module having improved output characteristics and high reliability.

The solar cell module according to the present invention will not be limited to the configurations described in the first to third embodiments. For example, in the configuration including low-refractive-index layer 8 on wiring 2 in the third embodiment, low-refractive-index layer 8 may be formed to have a two-layered structure of first low-refractive-index layer 8a and second low-refractive-index layer 8b, similarly to the second embodiment.

Furthermore, low-refractive-index layer 8 may be provided on wiring 2 and on fine line-shaped electrode 4A. The present invention is not limited to these, and various modifications can also be made within the spirit of the present invention.

### Examples

Hereinafter, the solar cell module according to the present invention will be specifically described while examples are given.

In the examples of the present invention, the solar cell modules according to the first to third embodiments are manufactured as follows. Description will be given on the manufacturing method below, while the process thereof is classified into steps 1 to 5.

### <Step 1> Formation of Photoelectric Conversion Body

First, prepared is an n type single crystal silicon substrate of approximately 125 mm², which has a resistivity of approximately 1 Ωcm and a thickness of approximately 200 μm. Next, with a CVD method, an i type amorphous silicon layer having a thickness of approximately 5 nm and a p type amorphous silicon layer having a thickness of approximately 5 nm are formed in this order on an upper surface of the n type single crystal silicon substrate.

Then, with the CVD method, an i type amorphous silicon layer having a thickness of approximately 5 nm and an n type amorphous silicon layer having a thickness of approximately 5 nm are formed in this order on a rear surface of the n type single crystal silicon substrate.

Subsequently, with a sputtering method, an ITO film having a thickness of approximately 100 nm is formed on each of the p type amorphous silicon layer and the n type amorphous silicon layer. With the above-mentioned step, photoelectric conversion bodies of solar cells according to the examples are produced.

### <Step 2> Formation of Collecting Electrode

Next, with a printing method, a collecting electrode having a shape to be described below is formed on each surface of the ITO films respectively disposed on the light receiving surface side and the rear surface side of the photoelectric conversion body by using an epoxy thermosetting silver paste.

For samples in examples 1 to 3 according to each of the first to third embodiments, fine line-shaped electrodes each having a width of approximately 100 μm and a thickness of approximately 30 μm are formed at a pitch of approximately 2 mm.

Furthermore, for each sample in examples 1 to 3 according to each of the first to third embodiments, two bus bar electrodes each having a length of approximately 122 mm, a width of approximately 1.0 mm and a thickness of approximately 30 μm are formed as connecting electrodes 4B perpendicularly to fine line-shaped electrode 4A.

### <Step 3> Formation of Low-Refractive-Index Layer

For the samples in examples 1 and 2, a low-refractive-index layer is formed on fine line-shaped electrode 4A.

For the sample of example 1, a paste-like material obtained by mixing silica nano particles into a silicone resin is applied onto fine line-shaped electrode 4A with a screen printing method. Subsequently, the paste-like material is heated and dried. Thereby, low-refractive-index layer 8 is formed so as to have a refractive index of approximately 1.34. At this time, low-refractive-index layer 8 having a width of approximately 150 μm and a thickness of approximately 20 μm is formed on fine line-shaped electrode 4A, but not on or in the vicinity of the connecting electrodes.

For the sample in example 2, the amount of the silica nano particles mixed into the silicone resin in the first low-refractive-index layer 8a is made larger than that in second low-refractive-index layer 8b. Thereby, first low-refractive-index layer 8a is formed to have a refractive index lower than that of second low-refractive-index layer 8b. In example 2, first low-refractive-index layer 8a having a refractive index of 1.29 is used. Then, first low-refractive-index layer 8a having a width of approximately 50 μm and a thickness of approximately 10 μm is formed on fine line-shaped electrode 4A, but not on or in the vicinity of the connecting electrodes. First low-refractive-index layer 8a is formed in a way that a lower surface of fine line-shaped electrode 4A is uncovered. The viscosity of the silicone resin paste including the silica nano particles is set higher so that a larger thickness can be obtained by the application. Next, second low-refractive-index layer 8b is formed over the lower surface of fine line-shaped electrode 4A and first low-refractive-index layer 8a, by using a similar paste to that of low-refractive-index layer 8 in example 1. At this time, second low-refractive-index layer 8b is formed to have a width of approximately 150 μm and a thickness of approximately 20 μm on fine line-shaped electrode 4A, but not on or in the vicinity of the connecting electrode.

The sample of example 3 will be described later since low-refractive-index layer 8 is formed after wiring connection.

### <Step 4> Connection of Wiring

Copper is used as a material of wiring 2 with the surface thereof being coated with solder. The width of the wiring is approximately 1.5 mm.

A resin adhesive including a thermosetting epoxy resin is applied onto the connecting electrode by use of a dispenser or the like. The adhesive has conductivity because nickel particles are included at a volume ratio of approximately 5% in the resin.

Then, in each of the solar cells of example 1 to 3, the wiring disposed on the connecting electrode is sandwiched by a heater from top and bottom of the wiring, and heated under a predetermined pressure. Subsequently, wiring 2 is adhered with an adhesive by hardening the adhesive.

For the sample in example 3, on wiring 2 disposed on the connecting electrode on the light receiving surface of the photoelectric conversion body, low-refractive-index layer 8 is formed to have a width of approximately 1.5 mm and a thickness of 50 μm. Low-refractive-index layer 8 is formed as follows. A paste-like material is obtained by mixing silica nano particles into a silicone resin to have a refractive index approximately 1.34. The pasty material is applied onto wiring 2 by use of a dispenser, and subsequently, heated and dried. Thereby, low-refractive-index layer 8 is formed so as to have a refractive index of approximately 1.34.

### <Step 5> Modularization

A sealing material sheet made of an EVA is placed on a surface protector made of a glass substrate. Subsequently, a plurality of solar cells connected to each other by wiring 2 are disposed on the sealing material sheet. Then, another sealing material sheet made of an EVA is placed on a plurality of solar cells. Thereafter, a rear-surface member having a three-layered structure of PET/aluminum foil/PET is disposed on the sealing material. Then, the above-mentioned members are integrated using a well-known method such as lamination method, so that a solar cell module of each example is structurally completed.

Through the above-mentioned process, the sample of example 1 according to the first embodiment, the sample of example 2 according to the second embodiment, and the sample of example 3 according to the third embodiment are formed.

### Comparative Example

The same sample as the sample according to the first embodiment is used except that no low-refractive-index layer 8 is formed.

### (Result)

Module output currents of the solar cell modules according to examples 1 to 3 and the comparative example are measured. As conditions for measurement, the standard conditions specified by JIS C 8918 are used, where spectral distribution is AM 1.5, radiant intensity is 1 kW/m², and module temperature is 25° C. Table 1 shows normalized module currents of the solar cell modules in the comparative example and examples 1 to 3. The normalized module current refers to a normalized value where the module current of the solar cell module in the comparative example is defined as 1.

TABLE 1

| | Normalized module current |
|---|---|
| Comparative example | 1 |
| Example 1 | 1.011 |
| Example 2 | 1.033 |
| Example 3 | 1.025 |

Table 1 shows that the values of the normalized module current in examples 1 to 3 are improved compared with the comparative example. In examples 1 and 2, the value of the normalized module current is improved since the light can be efficiently guided to the light receiving surface of the photoelectric conversion body by forming the low-refractive-index layer on the fine line-shaped electrode. In example 2, formation of the second low-refractive-index layer on the first low-refractive-index layer can make the inclination of the low-refractive-index layer steeper. Accordingly, light is more efficiently guided to the light receiving surface of the photoelectric conversion body in example 2 in comparison with example 1, and the value of the normalized module current is improved. In example 3, formation of low-refractive-index layer 8 on wiring 2 can make light be efficiently guided to the light receiving surface of photoelectric conversion body 5, and thus the value of the normalized module current is improved. Consequently, in examples 1 to 3, the values of the normalized module current are improved compared with the comparative example, resulting in an improved output of the solar cell module.

### Other Embodiments

As described above, obviously, the present invention includes various embodiments not described herein. The technical scope of the present invention is thus defined only by claimed elements according to the scope of claims as appropriate to the descriptions above.

For example, while the low-refractive-index layer is formed on either the fine line-shaped electrode or the wiring in the first to third embodiments, the low-refractive-index layer may be formed on the fine line-shaped electrode and on the wiring. In such a case, light can be further more efficiently guided to the light receiving surface of the photoelectric conversion body, and thereby characteristics of the solar cell module are further improved.

The invention includes other embodiments in addition to the above-described embodiments without departing from the spirit of the invention. The embodiments are to be considered in all respects as illustrative, and not restrictive. The scope of the invention is indicated by the appended claims rather than by the foregoing description. Hence, all configurations including the meaning and range within equivalent arrangements of the claims are intended to be embraced in the invention.

What is claimed is:

1. A solar cell module comprising:
a solar cell that comprises
a photoelectric conversion body and
a fine line-shaped electrode formed on a light receiving surface of the photoelectric conversion body, the fine line-shaped electrode extending in a first direction; and
a sealing material provided on a light entering side of the solar cell, wherein
the solar cell comprises a low-refractive-index layer disposed between a light receiving surface of the fine line-shaped electrode and the sealing material,
the low-refractive-index layer has a refractive index lower than a refractive index of the sealing material,
the low-refractive-index layer is provided to cover the light receiving surface of the fine line-shaped electrode, and
the low-refractive-index layer has an inclined surface, whose central portion projects in a cross section of the low-refractive-index layer taken along a second direction substantially perpendicular to the first direction, and
the cross section of the low-refractive-index layer becomes wider toward the light receiving surface of the photoelectric conversion body.

2. The solar cell module of claim 1, wherein the refractive index of the low-refractive-index layer is lower than 1.45.

3. The solar cell module of claim 1, wherein the low-refractive-index layer includes a hybrid material that is a mixture of an organic material and an inorganic material.

4. The solar cell module of claim 1, wherein the low-refractive-index layer includes a silicone resin.

5. The solar cell module of claim 1, wherein the low-refractive-index layer includes silica nano particles.

6. The solar cell module of claim 4, wherein the low-refractive-index layer includes a silane coupling material.

7. The solar cell module of claim 1, wherein the low-refractive-index layer includes a fluoropolymer.

8. The solar cell module of claim 7, wherein the low-refractive-index layer includes an amorphous fluorocarbon polymer.

9. The solar cell module of claim 1, further comprising
a wiring disposed between the fine line-shaped electrode and the sealing material, the wiring extending in the second direction, wherein
the low-refractive-index layer is provided to cover a surface of the fine line-shaped electrode exposed from the wiring.

10. The solar cell module of claim 1, wherein the low-refractive-index layer comprises:
a first low-refractive-index layer provided on an upper portion of the fine line-shaped electrode, which allows a lower surface of the fine line-shaped electrode to be exposed; and
a second low-refractive-index layer provided over the lower surface of the fine line-shaped electrode and the first low-refractive-index layer.

11. The solar cell module of claim 10, wherein a refractive index of the first low-refractive-index layer is lower than a refractive index of the second low-refractive-index layer.

12. The solar cell module of claim 10, further comprising
a wiring disposed between the fine line-shaped electrode and the sealing material so as to extend in the direction perpendicular to the first direction, wherein
the low-refractive-index layer is provided so as to cover a surface of the fine line-shaped electrode exposed from the wiring.

13. A solar cell module comprising:
a plurality of solar cells arranged in an arrangement direction;
a wiring extending in the arrangement direction and configured to electrically connect the solar cells disposed adjacent to each other; and
a sealing material provided on light entering sides of the plurality of solar cells wired to each other with the wiring, wherein
each of the solar cells comprises:
a photoelectric conversion body; and
a low-refractive-index layer disposed between a light receiving surface of the wiring and the sealing material,
the low-refractive-index layer has a refractive index lower than a refractive index of the sealing material,
the low-refractive-index layer is provided so as to cover a light receiving surface of the wiring, and
the low-refractive-index layer has an inclined surface being inclined, so that its central portion projects in a cross section of the low-refractive-index layer taken along a direction perpendicular to the arrangement direction, and that the cross section becomes wider toward a light receiving surface of the photoelectric conversion body.

14. The solar cell module of claim 13, wherein the refractive index of the low-refractive-index layer is lower than 1.45.

15. The solar cell module of claim 13, wherein the low-refractive-index layer includes a hybrid material that is a mixture of an organic material and an inorganic material.

16. The solar cell module of claim 13, wherein the low-refractive-index layer includes a silicone resin.

17. The solar cell module of claim 13, wherein the low-refractive-index layer includes silica nano particles.

18. The solar cell module of claim 16, wherein the low-refractive-index layer includes a silane coupling material.

19. The solar cell module of claim 13, wherein the low-refractive-index layer includes a fluoropolymer.

20. The solar cell module of claim 19, wherein the low-refractive-index layer includes an amorphous fluorocarbon polymer.
